(19) United States
(12) Patent Application Publication
(10) Pub. No.: US 2003/0201120 A1
(43) Pub. Date: Oct. 30, 2003

(54) Fastening system for electronic components

(75) Inventors: Steven Lo Forte, Copperton, UT (US); Brent Madsen, Providence, UT (US); Doug Sward, Midvale, UT (US); Rich Howe, Salt Lake City, UT (US); Alan Ottley, West Valley City, UT (US)

Correspondence Address: WORKMAN NYDEGGER (F/K/A WORKMAN NYDEGGER & SEELEY), 60 EAST SOUTH TEMPLE, 1000 EAGLE GATE TOWER, SALT LAKE CITY, UT, 84111, US

(73) Assignee: 3Com Corporation

(21) Appl. No.: 10/128,965

(22) Filed: Apr. 24, 2002

(51) Int. Cl. H05K 1/03

(52) U.S. Cl. 174/255

(57) ABSTRACT

A fastening system suitable for use in attaching a first component, having upper and lower surfaces, to a second component. The fastening system includes a mounting structure having a contact portion configured to be joined about a through hole defined by either the first or the second component and to receive the fastener after the fastener has passed through the through hole. Additionally, the mounting structure includes a standoff portion joined to the contact portion. The standoff portion is configured to receive the fastener so that the fastener resides in the mounting structure in a predetermined position with respect to the first and second components when the first and second components are joined together by the fastener.

### CROSS-REFERENCE TO RELATED APPLICATIONS

Not applicable.

### BACKGROUND

1. Technological Field

The present invention relates generally to fastening systems and related components. More particularly, embodiments of the present invention relate to a fastening system useful in joining electronic components, such as printed circuit boards, together while also facilitating achievement of a desired geometric configuration in the resulting electronic component assembly.

2. Related Technology

A virtually unlimited variety of devices require one or more printed circuit boards (“PCB”) in order to aid in implementation of various functionalities. Examples of such devices include personal data assistants (“PDA”), wireless telephones, video game machines, televisions, stereo equipment, medical equipment, computers, peripheral devices such as modems and printers, and media readers, such as compact disk drives and magnetic disk drives. Additionally, various types of expansion cards, such as the so-called mini Peripheral Component Interconnect (“PCI”) expansion cards typically employ one or more PCBs. Examples of such expansion cards include memory cards, modem cards, and wireless communication cards.

Often, the design of such devices is driven in part by a desire to maximize the functionality of the particular device. Maximization of utility within a predefined geometry is of particular interest to consumers, who generally desire ever-increasing functionality but are typically resistant to material increases in the size and/or weight of the device within which the PCB is employed. Such issues are particularly germane in the context of devices such as PDAs which derive at least some of their utility and desirability from their relatively small size.

One approach to enhancing the functionality of a device relates to the space limitations inherent on a particular PCB. Specifically, a given PCB has a finite amount of surface area available for the mounting of various electronic components and is, accordingly, limited in the functionality that it can effectively implement. The functionality of the particular PCB and/or the device in which the PCB is disposed can nonetheless be desirably enhanced by attaching another PCB to the main PCB.

Generally, such configurations involve securing a PCB to a mounting surface, where the receiving mounting surface is coplanar with respect to the PCB device which is to be mounted. One example of such an arrangement is a motherboard-daughterboard arrangement where a relatively smaller daughterboard is attached to a relatively larger motherboard. As suggested below however, geometric and other constraints often act to limit the applications in which such arrangements can be employed.

By way of example, the ability to enhance or increase functionality within a particular device, and/or produce other desirable results, is limited at least in part by geometric requirements, such as those imposed by the PCMCIA standard configurations, as well as various other requirements, with which the device utilizing the PCBs must conform. Such requirements are examples of factors that may make it desirable, in some instances, to join two or more PCBs together in a particular configuration to achieve production of an electronic component assembly having a desired configuration or arrangement.

One way to join two or more PCBs together would be to employ a fastener standoff or similar structure adapted to receive a fastener, a screw for example, and disposed in a hole defined by a first PCB in such a way that the fastener is able to pass through the first PCB and the fastener standoff and then engage a corresponding threaded portion in the second PCB that is to be attached to the first PCB. However, this type of approach may implicate certain undesirable effects.

At least some of such effects are related to the physical nature of the PCB. For example, PCBs generally are somewhat brittle and can be easily cracked or broken. In this configuration, using a technique such as press-fitting to install a metal fastener standoff in a through hole defined by a PCB could create undesirable stress and strain in the PCB that may ultimately lead to cracking and/or breakage. While processes other than press-fitting may be employed, those processes may implicate different, but equally problematic, results.

By way of example, another way to attach a fastener standoff to a PCB would be to simply solder the fastener standoff to a mating solder pad on the PCB. Thus, the fastener standoff would necessarily comprise a metallic material so as to insure a good bond with the solder pad on the PCB. This type of approach would tend to avoid some of the difficulties implicated by the somewhat brittle and fragile nature of PCBs and the effects thereon that are implicated by processes such as press-fitting.

However, a fastener standoff composed of a metal such as steel would require significant heating before reaching the appropriate soldering temperature. This is problem is especially acute where such standoffs, whether made of steel or other metals, are machined or otherwise manufactured from material configurations such as rod stock. In particular, the use of configurations such as rod stock implicates a standoff having relatively thick walls, and a correspondingly large thermal mass.

In order that heating of the relatively large thermal mass of such a fastener standoff could be implemented, the PCB would be required to spend a significant amount of time in a solder re-flow oven, thereby slowing down production rates and increasing the overall costs associated with the resulting assembly. Further, such additional heating could prove harmful to the PCB circuitry.

Finally, even if the aforementioned concerns could be adequately resolved, a fastener standoff has certain structural inherencies that would tend to thwart the use of manufacturing processes and machinery that employ vacuums or vacuum nozzles to facilitate component placement. Specifically, the presence of the hole in the fastener standoff, through which the fastener is received, would prevent a vacuum from being formed and thus may necessitate the use of other manufacturing techniques and processes to pick and place the fastener standoff on or in the PCB. The use of such alternative manufacturing techniques would likely complicate and/or increase the costs associated with the assembly of the PCB assembly.

Accordingly, what is needed is a fastening system having features directed to addressing the foregoing exemplary concerns, as well as other concerns not specifically enumerated herein. An exemplary fastening system should be capable of, among other things, joining two or more PCBs together in a particular desired arrangement, such as one wherein the receiving mounting surface is non-coplanar with the PCB device that is to be mounted, while doing so in a manner sensitive to geometric, and/or other, constraints imposed by a particular PCB, device, PCB standard, and/or application.

### BRIEF SUMMARY OF AN EMBODIMENT OF THE INVENTION

In general, embodiments of the invention are concerned with systems, structures and devices useful in joining components such as PCBs in such a way as to facilitate achievement of a particular geometric configuration in the resulting assembly.

In one embodiment of the invention, a mounting structure is provided that is generally in the form of a collar and includes a contact portion and a standoff portion joined to one another. In this embodiment, the contact portion is configured in such a way as to facilitate attachment of the mounting structure to a corresponding solder pad on a PCB. The standoff portion defines a recess as well as a hole adjacent to, and in communication with, the recess. In some embodiments of the invention, the recess thus defined extends below the lower surface of the PCB such that a fastener passing through the PCB and the hole defined by the standoff portion, and seated in the recess, assumes a desired position and/or orientation with respect to the PCB. In at least one embodiment of the invention, the mounting structure is configured such that the fastener lies entirely below the upper surface of the PCB when the fastener is seated in the recess. Moreover, the mounting structure is configured and arranged, in this exemplary embodiment, so that the component ultimately joined to the PCB by way of the mounting structure resides in a non-coplanar arrangement with respect to the PCB.

These and other, aspects of embodiments of the present invention will become more fully apparent from the following description and appended claims.

### BRIEF DESCRIPTION OF THE DRAWINGS

In order that the manner in which the above-recited and other advantages and features of the invention are obtained, a more particular description of the invention briefly described above will be rendered by reference to specific embodiments thereof which are illustrated in the appended drawings. Understanding that these drawings depict only typical embodiments of the invention and are not therefore to be considered limiting of its scope, the invention will be described and explained with additional specificity and detail through the use of the accompanying drawings in which:

FIG. 1 is an exploded perspective view illustrating various features of an embodiment of an electronic assembly that includes two PCBs and the fastening system;

FIG. 2 is a cross-section view illustrating various features of an embodiment of the electronic assembly depicted in FIG. 1;

FIG. 3A is a cross-section view illustrating various features of an embodiment of a mounting structure attached to a PCB;

FIG. 3B is a cross-section view illustrating the embodiment of the mounting structure illustrated in FIG. 3A used in conjunction with a fastener;

FIG. 4A is a cross-section view illustrating various features of an alternative embodiment of a mounting structure that includes a sleeve and a foot;

FIG. 4B is a cross-section view illustrating the embodiment of the mounting structure depicted in FIG. 4A used in conjunction with a fastener;

FIG. 5A is a cross-section view illustrating various features of an embodiment of a mounting structure disposed in a countersunk through hole defined by a PCB;

FIG. 5B is a cross-section view illustrating the embodiment of the mounting structure depicted in FIG. 5A used in conjunction with a fastener;

FIG. 6A is a cross-section view illustrating an embodiment of a mounting structure that is integral with a PCB;

FIG. 6B is a cross-section view illustrating the embodiment of the mounting structure depicted in FIG. 6A used in conjunction with a fastener;

FIG. 7A is a perspective view of an alternative embodiment of a mounting structure; and

FIG. 7B is a section view illustrating various aspects of the relationship between a PCB and the embodiment of the mounting structure illustrated in FIG. 7A.

### DETAILED DESCRIPTION OF SELECTED EMBODIMENTS OF THE INVENTION

Reference will now be made to figures wherein like structures will be provided with like reference designations. It is to be understood that the drawings are diagrammatic and schematic representations of various embodiments of the claimed invention, and are not to be construed as limiting the scope of the present invention in any way, nor are the drawings necessarily drawn to scale.

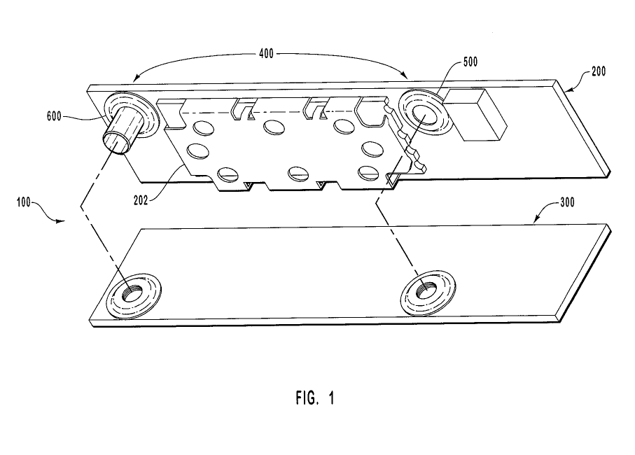

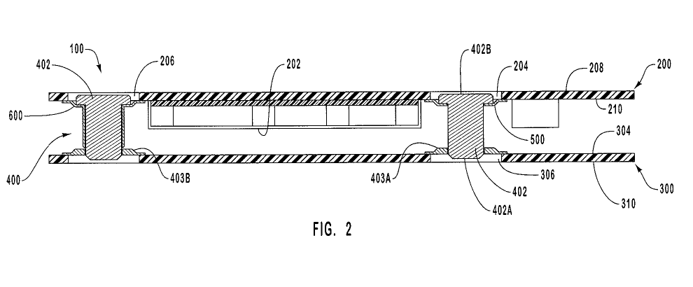

Attention is directed first to FIGS. 1 and 2 wherein an embodiment of an electronic assembly is denoted generally at 100. In general, electronic component assembly 100 includes a first printed circuit board (“PCB”) 200 joined to a second PCB 300 by way of a fastening system 400, and electronic component assembly 100 may comprise, for example, any of a variety of electronic components and devices such as, but not limited to, mini-PCI expansion cards.

Note that while the embodiment of fastening system 400 illustrated in FIG. 1 is depicted as being used in conjunction with an electronic component assembly 100, other embodiments of fastening system 400 may be used in any of a variety of applications or environments where one or more aspects of fastening system 400 are desired to be employed. Accordingly, the scope of the present invention should not be construed to be limited to the embodiments or the operating environments disclosed herein.

With continuing reference to FIGS. 1 and 2, electronic component assembly 100 may include any of a variety of electronic components, such as first PCB 200 and second PCB 300 discussed below, and may assume any of a number of different configurations. By way of example, some embodiments of electronic component assembly 100 take the form of a “mother-daughter” configuration wherein first PCB 200 comprises a daughterboard, having components such as radio 202 for example, attached to second PCB 300, comprising a motherboard. Of course, various other components having different functionalities may be substituted for radio 202. Note that, in general, the electronic circuitry (not shown) associated with first PCB 200 and second PCB 300 may be located on the respective upper and/or lower surfaces of first PCB 200 and second PCB 300.

In the exemplary embodiment illustrated in FIGS. 1 and 2, first PCB 200 and motherboard 300 are disposed in a non-coplanar arrangement with respect to each other. However, the scope of the invention should not be construed in any way to be limited to this exemplary arrangement, and various other arrangements may be employed consistent with the requirements of a particular application.

Note that in some instances, the motherboard is physically larger than the daughterboard and the daughterboard and motherboard may be joined together, either removably or permanently, consistent with the requirements of a particular application. By way of example, it may be desirable in some cases to supplement or enhance the functionality provided by the motherboard, in this case second PCB 300, by attaching one or more daughterboards, in this case first PCB 200, having particular desired functionalities. As another example, a daughterboard may be attached to a motherboard in order to take advantage of otherwise unused space within the component wherein the motherboard is employed.

Aspects of the nature of the connection implemented by fastening system 400 may vary from one application or environment to another. For example, in some embodiments of electronic component assembly 100, the connection between first PCB 200 and second PCB 300 may be substantially structural in nature where first PCB 200 is physically joined, or otherwise attached, to second PCB 300. Depending upon the application, operating environment, and/or other variables, PCB 200 may be permanently attached to second PCB 300, and in other cases, PCB 200 and PCB 300 may be removably attached to each other.

In other exemplary arrangements of electronic component assembly 100, the nature of the connection between first PCB 200 and second PCB 300 may be both structural and functional in nature. Specifically, in addition to physically joining first PCB 200 and second PCB 300 together, whether permanently or removably, some embodiments of fastening system 400 facilitate functional interaction between first PCB 200 and second PCB 300. By way of example, some embodiments of fastening system 400 may serve to electrically connect first PCB 200 and second PCB 300, such as by way of a mounting structure, discussed below. Other embodiments of fastening system 400 may, for example, serve to electrically ground first PCB 200 and/or second PCB 300. Generally, the aspects of the connection between PCBs, or between other components, implemented by way of fastening system 400, may be selected as desired based on the requirements of a particular application or operating environment.

In addition to assuming various physical configurations, embodiments of electronic component assembly 100 may also implement any of a variety of desired functionalities. For example, electronic component assembly 100 may comprise a modem card, wireless communication card, expanded memory card, radio communication card, or any other electronic component having one or more functional aspects implemented by way of one or more PCBs. In view of the foregoing, embodiments of the present invention disclosed herein should not be construed to limit the scope of the invention to any particular functionality or operating environment.

With continuing attention to FIGS. 1 and 2, various aspects of an embodiment of fastening system 400 are discussed in further detail. As indicated in FIGS. 1 and 2, the illustrated embodiment of fastening system 400 includes mounting structures 500 and 600. The illustrated embodiment is exemplary only however, and fastening system 400 may comprise various combinations of mounting structures. For example, some embodiments of fastening system 400 comprise only mounting structures 500, while yet other embodiments of fastening system 400 comprise only mounting structures 600. In some embodiments of the invention, mounting structures 500 and 600 comprise tin-plated cartridge brass or tin-plated low carbon steel. However, various other base materials and plating materials may be employed to suit the requirements of a particular application or operating environment.

As discussed herein, a variety of means may be employed to perform the functions disclosed herein, of a mounting structure. Thus, the embodiments of a mounting structure disclosed and discussed herein are but exemplary structures that function as a means for facilitating implementation of an electronic component profile. Accordingly, it should be understood that such structural configurations are presented herein solely by way of example and should not be construed as limiting the scope of the present invention in any way. Rather, any other structure or combination of structures effective in implementing the functionality disclosed herein may likewise be employed.

In at least some embodiments of the invention, mounting structures 500 and 600 comprise a relatively thin piece of metal that is rolled, stamped, or drawn into the illustrated configuration. The relative thinness of mounting structures 500 and 600 implicates a relatively small thermal mass that permits mounting structures 500 and 600 to be readily soldered to corresponding solder pads (not shown) disposed on first PCB 200, and/or second PCB 300, without necessitating the use of high heat levels and/or additional heating cycles in a solder re-flow oven.

In the illustrated embodiment, mounting structures 500 and 600 are substantially circular in shape and are attached to first PCB 200, for example, so as to be positioned substantially concentrically with corresponding through holes 204 and 206, respectively, defined by first PCB 200 and passing through upper surface 208 and lower surface 210. Both mounting structures 500 and 600 are sized to receive associated fasteners 402 passing through the through holes 204 and 206. In at least some embodiments of the invention, fasteners 402 comprise machine screws. However, any other type of fasteners effective in implementing one or more aspects of the functionality disclosed herein may alternatively be employed.

When fasteners 402 are seated in their respective mounting structures, fasteners 402 are positioned to engage corresponding connection member 403A and 403B positioned on second PCB 300 so that first PCB 200 can be securely attached to second PCB 300 by simply tightening fasteners 402. In one embodiment of the invention, the connection members 403A and 403B comprise structure that defines a threaded socket. However, any other structure(s) and/or arrangements effective in implementing the functionality of connection members 403A and 403B may alternatively be employed.

With respect to the embodiment illustrated in FIG. 2, connection members 403A and 403B, and/or fasteners 402, may be configured such that the respective ends 402A of fasteners 402 reside above the upper surface 304 of PCB 300 when first PCB 200 is fastened to second PCB 300. Such an arrangement would obviate the need for through holes 306 and 308 in second PCB 300. In one alternative embodiment however, fasteners 402 may be made sufficiently long as to pass completely through lower surface 310 of second PCB 300 and engage corresponding connection members positioned on, for example, one or more additional PCBs (not shown), thereby serving to fasten three or more PCBs together.

Generally, variables including, but not limited to, the number, length, type, and/or diameter of fasteners 402, as well as the configuration and position of connection members 403A and 403B, may be varied as required to suit a particular application or operating environment. By way of example, the length of fasteners 402 may be selected so as to facilitate achievement of a desired standoff distance between first PCB 200 and second PCB 300.

As suggested above, the fasteners 402 of the embodiment illustrated in FIGS. 1 and 2 permit first PCB 200 to be removably attached to second PCB 300. However, depending upon the requirements of a particular application or operating environment, some embodiments of fastening system 400 may be configured such that first PCB 200 is permanently joined to second PCB 300. In such an exemplary alternative embodiment, fastener 402 may simply comprise a metal post that is soldered both to corresponding mounting structure 500 and/or mounting structure 600 and to a solder pad (not shown) disposed on second PCB 300.

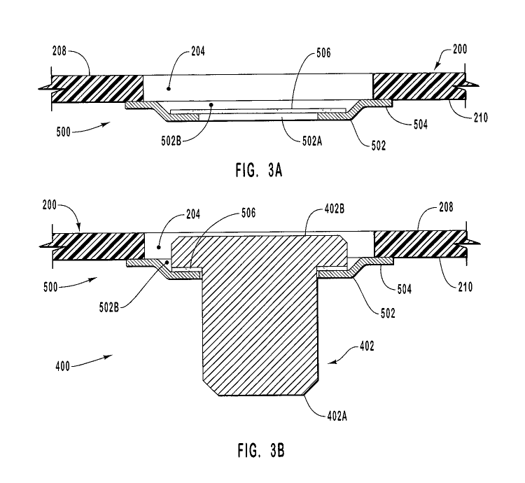

As suggested in FIGS. 1 and 2, mounting structure 500 and mounting structure 600 may be embodied in a variety of different ways. Directing attention now to FIGS. 3A and 3B, and with continuing attention to FIGS. 1 and 2, details are provided regarding selected features of exemplary embodiments of mounting structures 500 and 600.

Specifically, the illustrated embodiment of mounting structure 500 includes a standoff portion 502 that defines an opening 502A adjacent to, and in communication with, substantially concentric recess 502B. In general, opening 502A is sized to receive fastener 402 therethrough, and recess 502B is configured so as to provide a seat upon which head 402B of fastener 402 acts when fastener 402 is tightened. However, opening 502A and recess 502B may be configured and/or arranged as necessary to suit the requirements of a particular application. Accordingly, the configurations and arrangements of the structural features of the mounting structure, the aforementioned opening and recess for example, disclosed herein are exemplary only and should not be construed to limit the scope of the present invention in any way.

Mounting structure 500 further includes a contact portion 504 connected to standoff portion 502 and configured to be joined to solder pads (not shown) disposed on lower surface 210 of first PCB 200. In one embodiment of the invention, standoff portion 502 is integral with contact portion 504. However, various other configurations may be employed. By way of example, standoff portion 502 and contact portion 504 may comprise separate structures joined together by welding or other processes.

As suggested by the exemplary embodiment illustrated in FIGS. 3A and 3B, embodiments of mounting structure 500 are configured such that when fastener 402 is seated within recess 502B, fastener 402 resides in a particular desired position. As a result of the positioning of fastener(s) 402 in this way, various desirable results may be achieved. By way of example, embodiments of the invention are effective in facilitating implementation of a selected geometric profile for electronic component assembly 100.

In general, the desired positioning of fastener(s) 402 may be achieved, for example, by way of variations in the structure and/or positioning of the mounting structure and/or its specific components. With respect to such structure and positioning, the embodiment of mounting structure 500 illustrated in FIGS. 3A and 3B is configured so that when attached to first PCB 200 about through hole 204, recess 502B and, more generally, mounting structure 500, resides in its entirety substantially flush with and below lower surface 210 of first PCB 200.

As another example, mounting structure 500 may be arranged so that at least a portion of mounting structure 500 is interposed between lower surface 210 and upper surface 208 of first PCB 200. However, other configurations and arrangements of standoff portion 502 and contact portion 504, and more generally, mounting structure 500, may alternatively be employed in order to suit the requirements of a particular application and to facilitate achievement of a desired geometric profile or other desired result.

In the illustrated embodiment, for example, a very low profile is achieved wherein fastener 402 is positioned such that it resides, in its entirety, below upper surface 208 of first PCB 200. In one alternative embodiment, mounting structure 500 is configured such that the head 402B of fastener 402 is substantially flush with upper surface 208 of first PCB 200 when first PCB 200 is joined to second PCB 300, so that upper surface 208 is substantially even. In other alternative embodiment, mounting structure 500 is configured so that when fastener 406 is received within recess 502B, fastener 402 extends a desired distance above upper surface 208 of first PCB 200. In such an arrangement, recess 502B may inverted in order to achieve this positioning of fastener 402. In another exemplary embodiment (see FIG. 2), a low profile is achieved both on upper surface 208 of first PCB 200 as well as on lower surface 310 of second PCB 300.

In addition to standoff portion 502 and contact portion 504, at least some embodiments of mounting structure 500 include a consumable plug 506 that, in the illustrated embodiment, partitions opening 502A from recess 502B. In the illustrated embodiment, consumable plug 506 is disposed at the bottom of recess of 502B. However, consumable plug 506 may be disposed in any other location that facilitates implementation of the functionality disclosed herein. Accordingly, the illustrated location for consumable plug 506 is exemplary only.

In general, consumable plug 506 permits the use of pick-and-place manufacturing techniques, such as those that employ vacuum nozzles for example, in order to pick up mounting structure 500 and place it at a desired location on first PCB 200. Once mounting structure 500 is secured to first PCB 200, however, consumable plug 506 may be eliminated. Accordingly, consumable plug 506 comprises a material which permits use of vacuum nozzle placement of mounting structure 500, without impeding the subsequent insertion and/or removal of fastener 402.

In one embodiment of the invention, consumable plug 506 comprises a material that can be readily pierced, such as a scored polyester, and/or that will vaporize, be consumed, or otherwise be neutralized, during the re-flow processes associated with manufacture of first PCB 200. Alternatively, consumable plug 506 may comprise a material, such as solder, that liquefies at a pre-determined temperature so as to permit ready subsequent insertion of fastener 402, as illustrated in FIG. 3B. In some instances, consumable plug 506 may serve to prevent fastener 402 from falling out of mounting structure 500 during assembly of electronic component assembly 100 if fastener 402 is not otherwise supported. It should be noted that the foregoing are simply exemplary configurations of consumable plug 506. Accordingly, any other material or materials and/or configuration of consumable plug 506 that provide the functionality disclosed herein, may alternatively be employed.

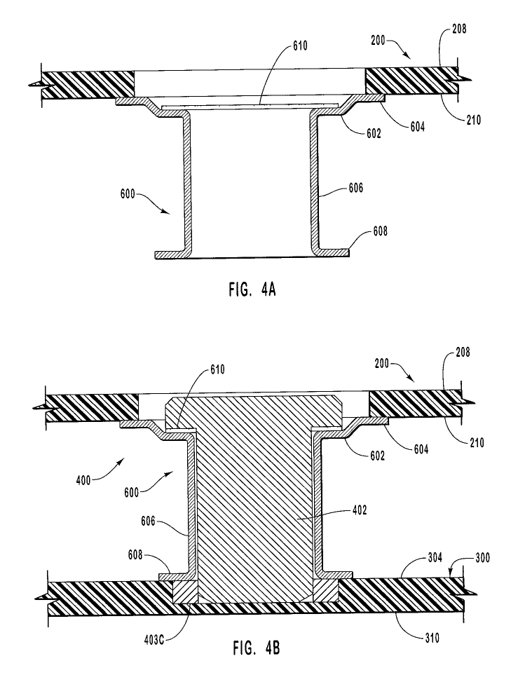

Directing attention now to FIGS. 4A and 4B, details are provided regarding selected features of an alternative embodiment of a mounting structure, denoted at 600. Note that, as certain aspects of mounting structure 600 are similar to aspects discussed above in conjunction with mounting structure 500, the discussion of the embodiment illustrated in FIGS. 4A and 4B will focus primarily on selected differences between mounting structure 500 and mounting structure 600. Such discussion, however, should not be construed to be an exhaustive enumeration of the differences between such embodiments.

Generally, mounting structure 600 includes standoff portion 602, a contact portion 604, a sleeve 606, and a foot 608. In one embodiment of mounting structure 600, standoff portion 602, contact portion 604, sleeve 606, and foot 608 are integral with each other. However, other arrangements may be employed where one or more of such components of mounting structure 600 are formed separately and subsequently attached to the remaining components.

As suggested in FIGS. 4A and 4B, sleeve 606 may be configured with a length such that a desired gap, or standoff distance, is introduced and maintained between first PCB 200 and second PCB 300 when fastener 402 is engaged with connection member 403C. In the illustrated embodiment, connection member 403C comprises structure that defines a threaded socket, however, any other structure providing the functionality disclosed herein may alternatively be employed. As suggested elsewhere herein, the embodiment of fastening system 400 illustrated in FIGS. 4A and 4B may additionally include a consumable plug 610.

Additionally, sleeve 606 and foot 608, may, in some applications, lend further structural integrity and stability to the connection between first PCB 200 and second PCB 300 of electronic component assembly 100 (see FIG. 2). Note that, in some applications, foot 608 of mounting structure 600 may be soldered to a corresponding solder pad on second PCB 300.

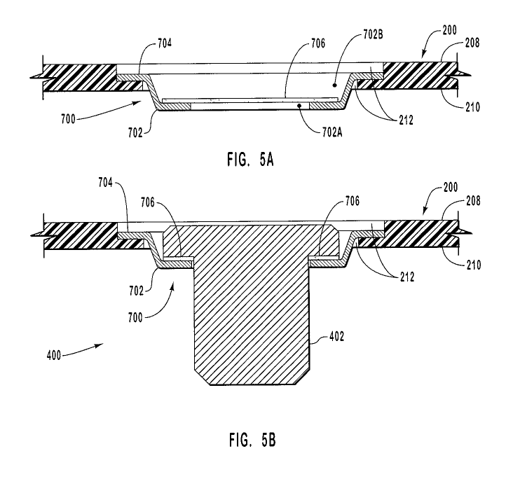

As suggested herein, fasteners 402 can be desirably positioned in a variety of ways, for example, by modifying the structure of the mounting structure and/or by varying the location of the mounting structure. Consistent with the foregoing, FIGS. 5A and 5B illustrate aspects of an embodiment of a mounting structure, denoted generally at 700, wherein a desired position of fastener 402 is achieved, at least in part, by way of the location of the mounting structure. Generally, the embodiment of the mounting structure illustrated in FIGS. 5A and 5B is similar in many regards to mounting structure 500 illustrated in FIGS. 3A and 3B. Accordingly, the discussion of FIGS. 5A and 5B will focus primarily on certain selected aspects of mounting structure 700 illustrated there.

In the embodiment illustrated in FIGS. 5A and 5B, mounting structure 700 is disposed within a countersunk through hole 212 defined by first PCB 200. The mounting structure 700 may be glued, soldered, or otherwise bonded to first PCB 200. When mounting structure 700 is positioned as shown, fastener 402 may correspondingly reside in a relatively higher position with respect to first PCB 200 than, for example, the position of fastener 402 illustrated in FIG. 3B. Alternatively, mounting structure 700 may be configured such that, even when mounting structure 700 is positioned as shown in FIG. 5B, the relative position of fastener 402 remains substantially the same as that illustrated in FIG. 3B. As another alternative, mounting structure 700 may be positioned such that the relative position of fastener 402 is lower than the relative position illustrated in FIG. 3B.

Generally then, variables such as, but not limited to, the configuration, and/or positioning, of embodiments of the mounting structure may be varied alone or in combination as desired to suit the requirements of a particular application or operating environment. Accordingly, the structure, as well as the arrangement, of the embodiments of the mounting structure disclosed herein are exemplary and are not intended to limit the scope of the invention in any way.

With continuing reference to FIGS. 5A and 5B, mounting structure 700 includes a standoff portion 702 and a contact portion 704. Additionally, standoff portion 702 of mounting structure 700 defines an opening 702A adjacent to, and in communication with, a concentric recess 702B. Further, mounting structure 700 may also include a consumable plug 706 disposed, for example, in recess 702B in such a way as to at least temporarily prevent communication between recess 702B and opening 702A.

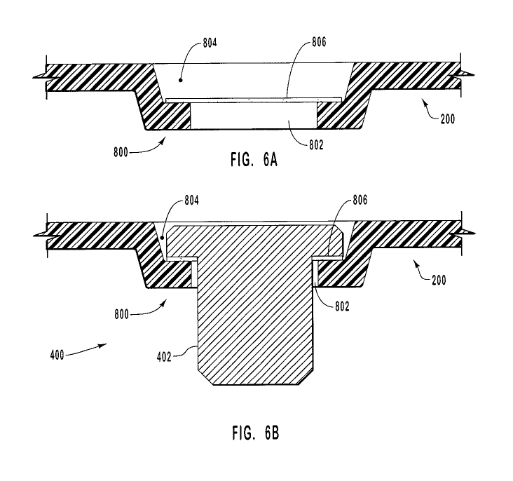

Directing attention now to FIGS. 6A and 6B, various aspects of another embodiment of a mounting structure are considered in further detail. In the embodiment illustrated in FIGS. 6A and 6B, the mounting structure, generally denoted at 800, does not comprise a discreet structure but rather is formed integrally with first PCB 200. Similar to other embodiments of the mounting structure specifically discussed herein, mounting structure 800 defines an opening 802 adjacent to, and in communication with, a substantially concentric recess 804. Further, mounting structure 800 may include a consumable plug 806.

As in the case of other embodiments of the mounting structure disclosed herein, mounting structure 800, by way of various aspects, its configuration and/or positioning for example, facilitates achievement of certain desired results with respect to electronic component assembly 100 (not shown). By way of example, mounting structure 800 aids in the attainment of a desired PCB surface profile and, at least in the case of the embodiment illustrated in FIGS. 6A and 6B, achieves this result by way of a configuration that permits fastener 402 to reside in a desired location.

In addition to the features noted above, mounting structure 800 may include a washer (not shown) disposed within recess 804 so that when fastener 402 is fully received within recess 804, fastener 402 is seated upon the washer. When arranged in this way, the washer may, among other things, serve to facilitate a relatively even distribution of the force exerted by fastener 402 as a result of its having been tightened. Such a washer may be glued or otherwise bonded to first PCB 200. Where a washer is employed, consumable plug 806 may be attached to the washer. Alternatively, consumable plug 806 may be attached to first PCB 200 in any location effective to facilitate implementation of the functionality of a consumable plug, as disclosed herein.

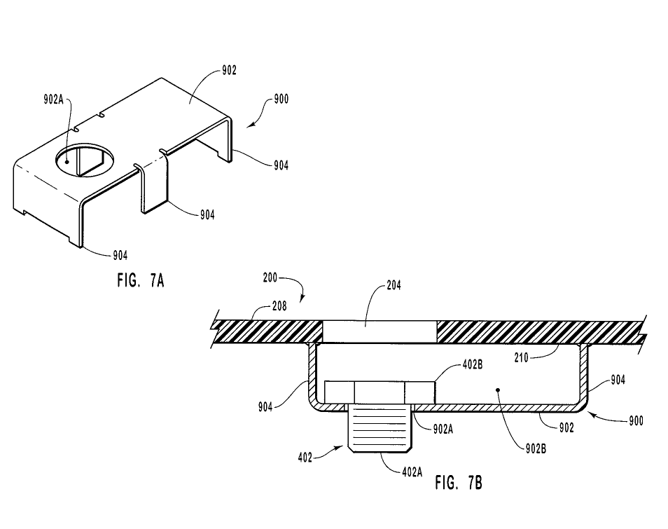

Directing attention now to FIGS. 7A and 7B, various aspects of another alternative embodiment of a mounting structure are illustrated. In the embodiment illustrated in FIGS. 7A and 7B, the mounting structure is generally denoted at 900, and may comprise any suitable material(s), including, but not limited to, tin-plated cartridge brass, and tin-plated low carbon steel. Mounting structure 900 includes a standoff portion 902 and a plurality of contact portions 904. In at least some embodiments, contact portions 904 are integral with standoff portion 902. Further, variables such as, but not limited to, the length, configuration, placement, and/or number of contact portions 904 may be varied as necessary to suit the requirements of a particular application.

Similar to other embodiments of the mounting structure disclosed herein, mounting structure 900 defines an opening 902A adjacent to, and in communication with, a recess 902B. Note that the size, geometry, number and/or placement of both opening(s) 902A and their respective corresponding fasteners 402, may be varied as desired. In similar fashion, the geometry of recess 902B may be reconfigured as required to suit a particular application.

Some embodiments of mounting structure 900 may include a consumable plug (not shown) disposed over opening 902A. Depending upon the configuration of the particular embodiment of mounting structure 900 however, a consumable plug may not be required. In the exemplary embodiment illustrated in FIGS. 7A and 7B, standoff portion 902 has sufficient surface area, even allowing for the presence of opening 902A, to allow the use of a vacuum nozzle for pick-and-place assembly and manufacturing procedures.

With continued attention to FIG. 7A, and directing more specific attention to FIG. 7B, details are provided concerning various aspects of the arrangement of mounting structure 900 with respect to fastener 402 and PCB 200. In the illustrated embodiment, the upwardly extending contact portions 904 are soldered to solder pads (not shown) disposed on lower surface 210 of PCB 200. As suggested above, mounting structure 900 may be positioned, prior to soldering, by pick-and-place processes or other manufacturing and assembly techniques. Once mounting structure 900 attached to PCB 200, fastener 402 may then be inserted into through hole 204 defined by PCB 200 and positioned on standoff portion 902 so that head 402B of fastener 402 resides on standoff portion 902, as shown in FIG. 7B.

One feature of this arrangement of mounting structure 900, fastener 402 and PCB 200, is that PCB 200 can be readily and securely fastened to another PCB (not shown) by way of fastener 402. Moreover, this arrangement is characterized by a very low profile on at least one side, as no portion of fastener 402 extends beyond upper surface 208 of PCB 200.

The described embodiments are to be considered in all respects only as exemplary and not restrictive. The scope of the invention is, therefore, indicated by the appended claims rather than by the foregoing description. All changes which come within the meaning and range of equivalency of the claims are to be embraced within their scope.

What is claimed is:

1. A mounting structure suitable for use in conjunction with a fastener used to attach first and second components together, both the first and second components having upper and lower surfaces, the mounting structure comprising:
(a) a contact portion configured to be joined to either the first or the second component and to receive the fastener; and
(b) a standoff portion joined to said contact portion, and said standoff portion configured to receive the fastener so that the fastener resides in the mounting structure in a predetermined position with respect to the first and second components when the first and second components are joined together by the fastener.

2. The mounting structure as recited in claim 1, wherein when the fastener resides in said predetermined position, any given portion of the fastener is located either substantially flush with or below the upper surface of the first component.

3. The mounting structure as recited in claim 1, wherein when the fastener resides in said predetermined position, the fastener is located, in its entirety, below the upper surface of the first component.

4. The mounting structure as recited in claim 1, wherein when the fastener resides in said predetermined position, the fastener is located, in its entirety, below the lower surface of the first component.

5. The mounting structure as recited in claim 1, wherein when the fastener resides in said predetermined position, the fastener is located, in its entirety, between the upper surface of the first component and the lower surface of the second component.

6. The mounting structure as recited in claim 1, wherein when the fastener resides in said predetermined position, at least a portion of the fastener extends beyond the upper surface of the first component.

7. The mounting structure as recited in claim 1, further comprising a consumable plug located proximate said standoff portion.

8. The mounting structure as recited in claim 1, wherein said standoff portion and said contact portion are integral with each other.

9. The mounting structure as recited in claim 1, wherein said standoff portion and said contact portion each comprise at least one of: tin-plated cartridge brass and tin-plated low carbon steel.

10. The mounting structure as recited in claim 1, further comprising a sleeve joined to said standoff portion, and a foot joined to said sleeve.

11. The mounting structure as recited in claim 1, further comprising a metal material.

12. An electronic component suitable for joining to a mating component by way of at least one fastener, the electronic component comprising:
(a) a printed circuit board including upper and lower surfaces and defining at least one through hole configured to receive the at least one fastener; and
(b) means for facilitating implementation of an electronic component profile when the electronic component and the mating component are joined together by the at least one fastener.

13. The electronic component as recited in claim 12, wherein said means for facilitating implementation of an electronic component profile electrically connects said printed circuit board with the mating component.

14. The electronic component as recited in claim 12, wherein said means for facilitating implementation of an electronic component profile electrically grounds said printed circuit board.

15. The electronic component as recited in claim 12, wherein when said predetermined electronic component profile has been implemented, said upper surface of said printed circuit board is substantially even.

16. The electronic component as recited in claim 12, wherein when said predetermined electronic component profile has been implemented, no portion of the at least one fastener extends substantially beyond said upper surface of said printed circuit board.

17. The electronic component as recited in claim 12, wherein said means for facilitating implementation of an electronic component profile causes the at least one fastener to assume a predetermined position with respect to said printed circuit board.

18. The electronic component as recited in claim 12, wherein said means for facilitating implementation of an electronic component profile comprises a mounting structure.

19. The electronic component as recited in claim 18, wherein said mounting structure comprises:
(a) a contact portion configured to be joined to said lower surface of said printed circuit board and to receive the at least one fastener; and
(b) a standoff portion joined to said contact portion.

20. The electronic component as recited in claim 19, wherein said mounting structure further comprises:
(a) a sleeve joined to said standoff portion; and
(b) a foot joined to said sleeve.

21. An electronic component, comprising:
(a) a printed circuit board including upper and lower surfaces and defining at least one through hole; and
(b) a mounting structure connected to said printed circuit board and substantially aligned with said at least one through hole, said mounting structure comprising:
(i) a contact portion; and
(ii) a standoff portion joined to said contact portion, said standoff portion defining both an opening and a recess adjacent said opening, said recess being located in a predetermined position with respect to said printed circuit board.

22. The electronic component as recited in claim 21, further comprising a consumable plug disposed proximate said opening and said recess.

23. The electronic component as recited in claim 21, wherein said mounting structure is integral with said printed circuit board.

24. The electronic component as recited in claim 21, wherein said mounting structure further comprises:
(a) a sleeve joined to said standoff portion; and
(b) a foot joined to said sleeve.

25. The electronic component as recited in claim 21, wherein said mounting structure comprises at least one of: tin-plated cartridge brass and tin-plated low carbon steel.

26. The electronic component as recited in claim 21, wherein said mounting structure is soldered to said printed circuit board.

27. The electronic component as recited in claim 21, wherein said at least one through hole defined by said printed circuit board comprises a countersunk through hole defined by said printed circuit board and said mounting structure is at least partially disposed in said countersunk through hole.

28. The electronic component as recited in claim 21, wherein when said recess is located in said predetermined position, a substantial portion of said recess is disposed below said upper surface of said printed circuit board.

29. A fastening system suitable for use in joining a printed circuit board having at least an upper surface, with another component, the selectable profile fastening system comprising:
(a) at least one fastener; and
(b) at least one mounting structure configured to receive said at least one fastener, said at least one mounting structure comprising:
(i) a contact portion; and
(ii) a standoff portion joined to said contact portion and configured so that when the printed circuit board and the component are joined together, said at least one fastener resides in a predetermined position with respect to the printed circuit board.

30. The fastening system as recited in claim 29, further comprising at least one connection member configured to be attached to the another component and to engage said at least one fastener.

31. The fastening system as recited in claim 30, wherein said at least one fastener and said at least one connection member are threaded.

32. The electronic component as recited in claim 29, wherein said mounting structure is integral with said printed circuit board

33. The fastening system as recited in claim 29, wherein when said at least one fastener resides in said predetermined position, any given portion of said at least one fastener is located either substantially flush with or below the upper surface of the printed circuit board.

34. The fastening system as recited in claim 29, wherein when said at least one fastener resides in said predetermined position, said at least one fastener is located, in its entirety, below the upper surface of the printed circuit board.

35. The fastening system as recited in claim 29, wherein said mounting structure further comprises:
(a) a sleeve joined to said standoff portion; and
(b) a foot joined to said sleeve, said foot being configured to be attached to the another component.

36. The fastening system as recited in claim 29, wherein said mounting structure comprises a metal material.

37. The fastening system as recited in claim 29, further comprising a consumable plug located proximate said standoff portion of said at least one mounting structure.

38. An electronic component assembly, comprising:
(a) a printed circuit board having upper and lower surfaces and defining at least one through hole;
(b) a component; and
(c) a fastening system joining said printed circuit board to said component, said fastening system comprising:
(i) at least one connection member attached to said component;
(ii) at least one fastener at least partially disposed within said at least one through hole and engaged with said at least one connection member; and
(ii) at least one mounting structure that receives said at least one fastener, said at least one mounting structure attached to said printed circuit board about said at least one through hole and comprising:
(1) a contact portion; and
(2) a standoff portion joined to said contact portion and configured so that said at least one fastener resides in a predetermined position with respect to said printed circuit board.

39. The electronic component assembly as recited in claim 38, wherein said component comprises a printed circuit board.

40. The electronic component assembly as recited in claim 38, wherein said mounting structure further comprises:
(a) a sleeve joined to said standoff portion; and
(b) a foot joined to said sleeve, said foot being attached to said component.

41. The electronic component assembly as recited in claim 38, wherein when said at least one fastener resides in said predetermined position, any given portion of said at least one fastener is located either substantially flush with or below said upper surface of said printed circuit board.

42. The electronic component assembly as recited in claim 38, wherein when said at least one fastener resides in said predetermined position, said at least one fastener is located, in its entirety, below said upper surface of said printed circuit board.

43. The electronic component assembly as recited in claim 38, wherein said at least one fastener and said at least one connection member are threaded.

44. The electronic component assembly as recited in claim 38, wherein said mounting structure is integral with said printed circuit board.

45. The electronic component assembly as recited in claim 38, wherein said mounting structure comprises a metal material.

46. The electronic component assembly as recited in claim 38, wherein said component and said printed circuit board are disposed in a non-coplanar arrangement with respect to each other.

47. A mounting structure suitable for use in conjunction with a fastener used to attach first and second components together, both the first and second components having upper and lower surfaces, the mounting structure comprising:
(a) at least one contact portion configured to be joined to either the first or the second component; and
(b) a standoff portion joined to said at least one contact portion, and said standoff portion configured to receive the fastener so that the fastener resides in the mounting structure in a predetermined position with respect to the first and second components when the first and second components are joined together by the fastener.

48. The mounting structure as recited in claim 47, wherein when the fastener resides in said predetermined position, any given portion of the fastener is located either substantially flush with or below the upper surface of the first component.

49. The mounting structure as recited in claim 47, wherein said at least one contact portion comprises a plurality of contact portions.

50. A mini-PCI expansion card, comprising:
(a) a printed circuit board having upper and lower surfaces and defining at least one through hole;
(b) a component; and
(c) a fastening system joining said printed circuit board to said component, said fastening system comprising:
(i) at least one connection member attached to said component;
(ii) at least one fastener at least partially disposed within said at least one through hole and engaged with said at least one connection member; and
(ii) at least one mounting structure that receives said at least one fastener, said at least one mounting structure attached to said printed circuit board about said at least one through hole and comprising:
(1) a contact portion; and
(2) a standoff portion joined to said contact portion and configured so that said at least one fastener resides in a predetermined position with respect to said printed circuit board.
